(19) United States
(12) Patent Application Publication
(10) Pub. No.: US 2010/0044682 A1
(43) Pub. Date: Feb. 25, 2010

(54) CHARGE INJECTION LAYER FOR ELECTRO-OPTICAL DEVICES

(75) Inventors: Hendrik Jan Bolink, Valencia (ES); Eugenio Coronado Miralles, Valencia (ES)

Correspondence Address: LADAS & PARRY LLP, 26 WEST 61ST STREET, NEW YORK, NY, 10023, US

(73) Assignee: UNIVERSITAT DE VALENCIA, Valencia (ES)

(21) Appl. No.: 12/301,243

(22) PCT Filed: May 7, 2007
(86) PCT No.: PCT/EP2007/054405

§ 371 Date: Nov. 10, 2009

(30) Foreign Application Priority Data
May 30, 2006 (ES) 200601510

(51) Int. Cl. H01L 51/54; C08K 5/18; C08G 75/02; C08G 73/02

(52) U.S. Cl. 257/40; 524/257; 524/609; 524/577; 524/612; 257/E51.027

(57) ABSTRACT

The present invention relates to charge injection from metallic conductors to semiconductor or insulation materials based on organic or inorganic molecules and macromolecules with electrical or optical properties, and specifically to a new charge injection layer for electro-optical devices comprising a polymer with conjugated units and a salt mixed with the aforementioned polymer, characterized in that the oxidation state of the polymer is not modified when it is mixed with the salt. Despite the fact that there is no change in the oxidation state of the polymer, the polymer and salt mixture according to the invention makes it possible for a high enough number of charges to reach the optically active layer, such that the efficiency in the charge injection process is increased up to levels exceeding even those provided by the standard PEDOT.

### FIELD OF THE INVENTION

The present invention relates to the injection of charges from metallic conductors to semiconductor or insulating materials based on organic or inorganic molecules and macromolecules with electrical or optical properties, and specifically to a new charge injection layer for electro-optical devices comprising a polymer with conjugated units and a salt mixed with the aforementioned polymer, characterized in that the oxidation state of the polymer is not modified when it is mixed with the salt.

### BACKGROUND OF THE INVENTION

Molecular materials with optical properties are currently used in several types of devices, such as in solar cells^{[}1, 2] and light emitting diodes (OLEDs)^{[}3, 4]. Furthermore, molecular materials with electronic properties are also used in FET transistors (Field Effect Transistors). OLED devices (Organic Light Emitting Diodes) are commercially interesting because they suggest the possibility of the low-cost manufacture of planar displays formed from individual high-density imaging elements (pixels) with a high electroluminescence efficiency, long lifetimes and a high brightness. It can also be considered that OLEDs can be useful for general lighting applications. Companies such as Philips, Osram and General Electric have large research programs on this application of OLED technology.

Generally, charge injection from a metallic conductor to a molecular material is not easy. The process depends on many factors, such as the Fermi level of the metal, the energy of the molecular orbitals (specifically of the highest occupied molecular orbital, the HOMO orbital, and of the lowest unoccupied molecular orbital, the LUMO orbital), and the conductivity of the molecular material. The surface of the metallic conductor furthermore significantly affects the formation of an optimal interface. In optoelectronic devices in which the light has to enter or exit from inside the device it is necessary to use a transparent electrode. The most frequently used transparent electrode is based on indium tin oxide (ITO). This ITO electrode works as a good conductor, but its surface is not perfectly planar at a nanometric level. Its work function furthermore does not coincide with the HOMO of most molecular semiconductor materials. The metal used as a counter electrode is usually, in the case of OLEDs, a metal with a low work function so as to coincide with the LUMO of the active optoelectronic semiconductor material. The fact that the energy of the electrons in these electrodes is high makes the interfaces (molecular semiconductor-metal) very reactive. Therefore, the devices are encapsulated to protect them from the interaction of environmental oxygen and water.

Optoelectronic molecular materials generally have a very low charge mobility and therefore it is necessary that the films made of this material, which are to be placed between the two metallic electrodes, are very thin. They are usually prepared with a thickness of the order of 100 up to 500 nm. Such thin films in combination with the not completely planar surface of the ITO gives rise to the formation of weak points in the devices, in which points short-circuits may occur during the operation of the device, reducing the lifetime thereof. To prevent this from happening, a conductive polymer is used in electro-optical devices in general and in current OLEDs in particular which has the function of flattening the surface of the ITO (FIG. 1), in addition to injecting charges in the luminescent material. Therefore, electro-optical devices usually consist of at least two layers besides the electrodes: a charge injection layer and another layer which is the one that performs the main function (in OLEDs: charge transport and light generation; in solar cells: light absorption and charge dissociation, etc.). Molecules or polymers having a HOMO level similar to that of the materials used for the optoelectronic function are normally used as injection materials.

However, in many cases the polymer used for the charge injection in its normal state is not sufficiently conductive for this application. As a result, in order to increase the conductivity of conjugated polymers a strong oxidizing agent (or in some cases a reducing agent) is added to them as a dopant, which extracts electrons from the molecular semiconductor and therefore leaves it in its oxidized state, drastically increasing its conductivity. As with crystalline semiconductors, this process is referred to as “doping” and involves an electrochemical change in the polymer.

Therefore, the dopants normally used up until now are not electrochemically inactive, such that they may oxidize or reduce the polymer. To this effect see, for example, patent document U.S. 2004/0209114 A1, which discloses electroluminescent devices comprising pyrylium salts or its derivatives as a partially oxidized charge transport material due to the reaction with a strong oxidizing agent used in a charge transport layer. In their normal state, these salts are electrochemically active and when they are used as dopants of the polymer forming the main component of the charge injection layer, they act as oxidizing agents of the polymer.

Furthermore, conjugated conductive polymers based on polythiophenes or polyanilines that are always “doped” so as to increase their conductivity (see for example patent document U.S. Pat. No. 6,730,416) are being used today in virtually all cases. These polymers are not soluble in any solvent and they may only be dispersed in solvents in combination with a surface-active molecular material. The example that is most widely used is based on polyethylenedioxythiophene (PEDOT), dispersable with the surface-active polymer polystyrene sulfonate (PSS), which is a dispersion in water. This material is known on the market as Baytron P, marketed by HC-Starck. This insolubility in solvents logically involves a problem when considering a technique for preparing polymers with a layer typically having a thickness of about 100 nm by means of processes from non-aqueous solutions. Furthermore, to eliminate water as a solvent in the process of preparing the devices is desirable according to the reactivity of the semiconductor materials and metals with a low work function with water.

Therefore, the problem to be solved by the person skilled in the art consists of providing a new charge injection layer for its use in optoelectronic devices which involves an alternative to those of the prior art which require a polymer that must be oxidized or reduced and that has high efficiency in the charge injection process.

The solution to this problem is based on the fact that the inventor has identified that it is possible to obtain a high efficiency charge injection in an OLED device by means of the use of a charge injection layer comprising a polymer having conjugated units and a salt mixed with the aforementioned polymer, said layer characterized in that the oxidation state of the polymer is not modified when it is mixed with the salt. Despite the fact that there is no change in the oxidation state of the polymer, the polymer and salt group according to the invention makes it possible for a sufficient number of charges to reach the optically active layer. In absence of the salt, the devices are less efficient due to the fact that the number of charges reaching the optically active layer is insufficient.

The preferred polymer is a polymer having a high concentration of molecular units of aromatic amines, such as for example triphenylamine, carbazole, (N,N,(diphenyl)-N′,N′di-(alkylphenyl)-4,4′-biphenyldiamine), (pTPDs), diphenylhydrazone, etc., i.e. molecules able to transport holes, as described for example in the book: “Organic Photoreceptors for Imaging Systems”, appendix 3, by Paul M. Borsenberger and David S. Weiss, Marcel Dekker, Inc, N.Y. 1998. These polymers are known for their ability to transport holes and for their high HOMO levels. An example of this type of polymers is poly(N′-4-butylphenyl-N-N-diphenyl-amine) (abbreviated hereinafter as “pTPD”) having the following structure:

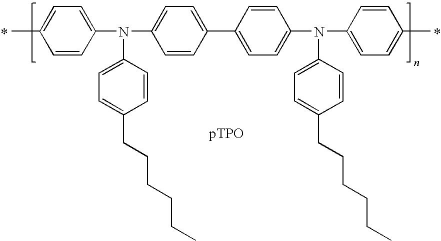

This polymer is completely soluble in chlorobenzene so it can easily be prepared from a solution in said solvent. The inventor has identified that the addition of a salt to the polymeric layer, preferably tetrabutylammonium hexafluorophosphate salt, increases the efficiency in the charge injection process up to levels exceeding even those provided by the standard PEDOT.

Accordingly, a first aspect of the invention is aimed at a charge injection layer for electro-optical devices comprising a polymer having conjugated units and a salt mixed with the aforementioned polymer, said layer characterized in that the oxidation state of the polymer is not modified when it is mixed with the salt.

A second aspect of the invention is aimed at the use of the charge injection layer for electro-optical devices such as molecular OLEDs, TFTs and solar cells.

An advantage of the charge injection layer of the invention is that it facilitates the preparation of the conductive polymer/electroluminescent material group when a solution-based preparation technique is used. When said technique is to be used, the addition of a second layer (the electroluminescent material layer) to the first layer (the charge injection layer) is not at all a trivial matter, since the solvent used to dissolve the material of the second layer may also dissolve the first layer when the second layer of material is deposited.

Another advantage of the charge injection layer of the invention is that the devices incorporating it can be produced without using water as a solvent, which may be beneficial for the stability and efficiency of the devices.

Another advantage is that the injection layer is in its most energetically stable state, not reduced or oxidized, and therefore is less reactive and more stable than other injection layers that are in the oxidized or reduced state.

An addition advantage of the charge injection layer of the invention is that the amount of light that is emitted from an optoelectronic device according to the current passing through the device is greater when a charge injection layer based on the polymer comprising conjugated units plus the salt of the present invention is used than when this same polymer is used without salt, or when a conductive polymer such as PEDOT:PSS is used. In addition to more light generation per current unit, it is also generating light at lower voltages, which results in a more energy-efficient device.

### BRIEF DESCRIPTION OF THE DRAWINGS

FIG. 1: Scheme of an OLED based in materials that can be processed from a solution.

FIG. 2: Depiction of the conductive polymer of an OLED using the charge injection layer of the invention.

FIG. 3: Depiction of the traditional conductive polymer of an LEEC.

FIG. 4: Depiction of the current density and luminescence of three different OLED devices using different charge injection layers of charges against the applied voltage.

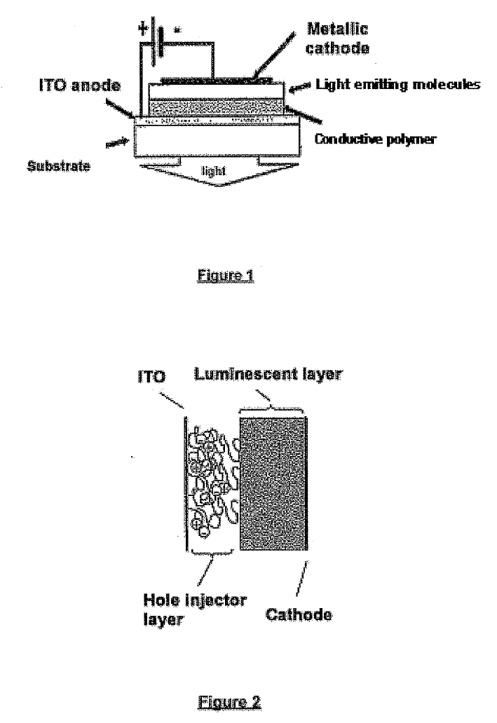

### DETAILED DESCRIPTION OF THE INVENTION

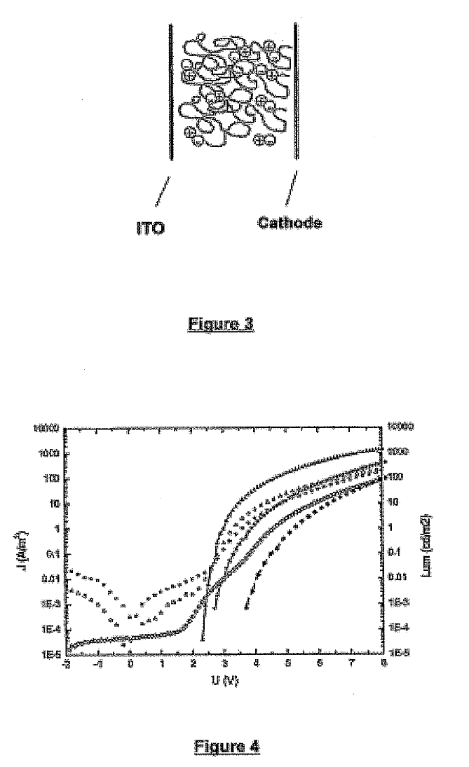

As far as the inventor is aware, there is only one additional example of OLEDs in the prior art in which inorganic salts are added to molecular materials for improving the charge injection. This occurs in international publication WO2006011090 applied to solid-state LEEC cells (Light Emitting Electrochemical Cell). FIG. 3 shows the depiction of an LEEC, in which the ions are represented by positive and negative circles, whereas the light emitting molecules are drawn as curved lines. The huge difference between this type of devices (LEECs) and those of the present invention can be seen when comparing FIG. 3 with FIG. 2, namely: in LEECs (FIG. 3), the charges are distributed throughout the luminescent material, whereas in the devices of the present invention (FIG. 2) the ions are found only in the charge injection layer, between the anode (ITO) and the light emitting layer. This causes the device activation time to be very long in LEECs, ranging from several seconds up to hours, depending on the type of ions and the light emitting material used, whereas the devices of the present invention have activation times of less than one second.

In a preferred embodiment of the invention, the charge injection layer comprises a polymer having conjugated units, which is completely soluble in chlorobenzene, to which an electrochemically inactive salt with respect to the polymer has been added, such as tetrabutylammonium hexafluorophosphate salt in an interval 0.001% to 10% in relation to the weight of the polymer. As a result of its solubility in chlorobenzene, when depositing the electroluminescent material it is possible to deposit said material dissolved in any other solvent that is not chlorobenzene without redissolving the already deposited layer. Furthermore, when the salt is selectively added to the charge injection layer, a possible negative interaction with the light emitting materials is prevented.

The polymer comprising conjugated units used in the charge injection layer of the present invention is preferably poly(N′-4-butylphenyl-N-N-diphenyl-amine) (“pTPD”). It is a polymer comprising conjugated units with a low oxidation potential, which is very important for charge transport. Generally speaking, those molecules having amine groups and aromatic groups with a low oxidation potential, or in other words those molecules in which it is easy for an electron to escape, may be used in the present invention as a conductive polymer. Accordingly, the polymer comprising conjugated units used in the charge injection layers of the present invention is selected from the groups consisting of:
a) molecularly doped polymers containing arylamine molecules as dopants at a concentration of 1-80%, preferably 10-60% and most preferably 30-50% (w/w);
b) neutral conjugated polymers, such as polythiophenes, polyphenylenes, polyanilines, polypyrrole, polyphenylenevinylenes and the like and their derivatives;
c) conjugated polymers containing neutral arylamines, preferably with an arylamine concentration exceeding 10% (w/w), preferably exceeding 40% (w/w) and most preferably exceeding 60% (w/w).

The preferred polymer comprising conjugated units used in the charge injection layer of the present invention is pTPD.

The inorganic salt used in the present invention must be a salt having at least one large ion that can be dissociated and it must further be soluble in the common solvent with the polymer used for the charge injection layer in order to be mixed with it at the molecular level.

The salt used in the present invention is preferably tetrabutylammonium hexafluorophosphate.

The charge injection layers of the invention are prepared in solution by dissolving the polymer and a small amount of the salt in chlorobenzene. Films are prepared from this solution using techniques known by the persons skilled in the art, such as the spin coating technique.

### EXAMPLE

FIG. 4 shows the results obtained in the current density (open symbols) and luminescence (closed symbols) parameters compared to the voltage applied by an OLED device with a blue light emitting material and three different hole injection layers: A) with the standard conductive polymer “PEDOT:PSS” (asterisks) ; B) with the polymer comprising undoped conjugated units “pTPD” (diamonds); C) with the polymer comprising conjugated units “pTPD” doped with 0.01% tetrabutylammonium hexafluorophosphate salt (triangles). In this figure it can be seen that the presence of the aforementioned salt considerably increases the efficiency in the charge injection process up to levels exceeding even those of the standard PEDOT. In the absence of the aforementioned salt, the efficiency in the charge injection progress is considerably less.

### LITERATURE

[1] U. Bach, D. Lupo, P. Comte, J. E. Moser, F. Weissörtel, J. Salbeck, H. Spreitzer, M. Grätzel, Nature 1998, 395, 583.
[2] G. Yu, J. Gao, J. Hummelen, F. Wudl, A. J. Heeger, Science 1995, 270, 1789.
[3] C. W. Tang, S. A. Vanslyke, Appl. Phys. Lett. 1987, 51, 913.
[4] J. H. Burrouches, D. D. C. Bradley, A. R. Brown, R. N. Marks, K. Mackay, R. H. Friend, P. L. Burn, A. B. Holmes, Nature 1990, 347, 539.

1. A charge injection layer for electro-optical devices comprising a polymer having conjugated units and a salt mixed with the cited polymer, characterized in that the oxidation state of the polymer is not modified when it is mixed with the salt.

2. A charge injection layer according to claim 1, wherein the polymer having conjugated units is selected from the group consisting of:
a) molecularly doped polymers containing arylamine molecules as dopants at a concentration of 1-80%, preferably 10-60% and most preferably 30-50% (w/w);
b) neutral conjugated polymers, such as polythiophenes, polyphenylenes, polyanilines, polypyrrole, polyphenylenevinylenes and their derivatives;
c) polymers containing chemically bound neutral arylamines, preferably having an arylamine concentration exceeding 10% (w/w) , preferably exceeding 40% (w/w) and most preferably exceeding 60% (w/w).

3. A charge injection layer according to claim 1, wherein the polymer having conjugated units is poly (N′-4-butylphenyl-N-N-diphenyl-amine).

4. A charge injection layer according to claim 1, wherein the salt is tetrabutylammonium hexafluorophosphate.

5. A charge injection layer according to claim 1, wherein the polymer having conjugated units and the salt are both soluble in at least one common solvent.

6. A charge injection layer according to claim 5, wherein the common solvent is an organic solvent.

7. A charge injection layer according to claim 6, wherein the organic solvent is selected from the group consisting of acetonitrile, dichloromethane, chloroform, toluene, benzene, chlorobenzene, cyclohexane, nitrobenzene, pyridine, piperidine, tetrahydrofuran and dimethylformamide.

8. A charge injection layer according to claim 7, wherein the organic solvent is chlorobenzene.

9. A charge injection layer according to claim 1, wherein the salt is added at a concentration between 0.001% and 10% (w/w) with respect to the polymer having conjugated units.

10. A charge injection layer according to claim 1, wherein the salt is added at a concentration between 0.01% and 1% (w/w) with respect to the polymer having conjugated units.

11. A charge injection layer according to claim 1, wherein the salt is added at a concentration between 0.1% and 0.5% (w/w) with respect to the polymer having conjugated units.

12. An electro-optical device comprising the charge injection layer of claim 1, plus a layer of an optically active material, an anode and a cathode.

13. The device of claim 12, selected from the group consisting of an organic light emitting diode (OLED) , a solar cell or a TFT display.

14. The device of claim 12, wherein the anode is made of ITO (indium tin oxide).

15. The device of claim 12, wherein the hole injection layer is soluble in a solvent in which the optically active material is insoluble.

16. The device of claim 12, wherein the hole injection layer is soluble in chlorobenzene and the optically active material is insoluble in chlorobenzene.

17. The use of the charge injection layer of claim 1, as a conductive material or charge or holes transport material in an electro-optical device.

18. The use of the charge injection layer of claim 16, wherein the electro-optical device is an OLED (organic light emitting diode), a TFT (thin film transistor) or a molecular solar cell.
